(19) United States
(12) Patent Application Publication
(10) Pub. No.: US 2007/0085551 A1
(43) Pub. Date: Apr. 19, 2007

(54) Calibration jig and calibration apparatus having the same

(76) Inventors: Seung-Ho Jang, Cheonan-si (KR); Chul-Woong Jang, Cheonan-si (KR); Se-Kyung Oh, Seongnam-si (KR); Min-Seok Jang, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 11/580,049

(22) Filed: Oct. 13, 2006

(30) Foreign Application Priority Data
Oct. 14, 2005 (KR) 2005-97028

(51) Int. Cl. G01R 35/00

(52) U.S. Cl. 324/601

(57) ABSTRACT

A calibration jig for adjusting timing and an apparatus equipped with such a calibration jig, including calibration block, at least one calibration board attached to the calibration block to form a securing platform for at least one test component, and a plurality of calibration terminals integral to the calibration board to provide improved calibration accuracy and timing.

### BACKGROUND OF THE INVENTION

1. Field of the Invention

The present invention relates to a calibration jig and a calibration apparatus having the same. More particularly, the present invention relates to a novel calibration jig and calibration apparatus employed for adjusting timing of input/output signals during testing of semiconductor packages.

2. Description of the Related Art

In general, semiconductors may be tested after a manufacturing process is complete to ensure proper operation and lack of defects. Such testing may include application of test signals to a semiconductor device, measuring a response of the semiconductor device, and comparing the measured response to a designed response. Any deviation between the measured and designed responses may be adjusted and remedied.

An apparatus for testing semiconductor devices may include a tester head and a die under test (DUT), i.e., a semiconductor device to be tested, mounted on the tester head. The tester head may include a driver, which may generate test signals, i.e., input signals, at predetermined times to the DUT, and a comparator, which may receive and analyze output signals at predetermined times from the DUT in response to the driver's test signals. Such testing may require precise control of timing of the input/output signals.

However, when an input signal is generated and transmitted into the DUT, a time deviation may be generated as a result of the length of the transmission line(s) between the driver and DUT and/or the number of the outer DUT terminals that receive the input signals. Subsequently, the timing of the DUT output signals and their analysis may be extended, thereby causing inaccurate overall timing and test results. Accordingly, it may be desirable to adjust the timing of the input/output signals with a calibration process in order to account for accurate signal deviation and/or degradation.

Known calibration apparatuses have either poor calibration accuracy or they require complex construction, lengthy procedure, and complicated operation to complete the calibration procedure. Therefore, there remains a need for a calibration jig capable of transmitting calibration signals to secured semiconductor devices thereon in a relatively short time, and an apparatus equipped with such a calibration jig in order to provide improved calibration accuracy.

### SUMMARY OF THE INVENTION

The present invention is therefore directed to a calibration jig and an apparatus employing the same, which substantially overcome one or more of the problems due to the limitations and disadvantages of the related art.

It is therefore a feature of an embodiment of the present invention to provide a calibration jig having such a structure that is capable of completing a calibration procedure in a relatively short time.

It is another feature of an embodiment of the present invention to provide a calibration apparatus equipped with a calibration jig and capable of correcting timing of a semiconductor package tester with improved accuracy.

At least one of the above and other features of the present invention may be realized by providing a calibration jig for adjusting timing that includes a calibration block, at least one calibration board attached to the calibration block to form a securing platform for at least one test component, and a plurality of calibration terminals integral to the calibration board.

The calibration terminals may have a configuration corresponding to a configuration of outer terminals of the test component, and the calibration terminals may include conductive balls. The calibration terminals may also electrically connect the test component to a calibration source. The test component may be a semiconductor package.

The calibration jig may include a plurality of calibration boards. The calibration board of an embodiment of the present invention may be detachable.

In another aspect of the present invention there is provided a calibration apparatus that includes a tester head, a calibration block attached to the tester head, at least one calibration board attached to the calibration block to form a securing platform for at least one test component, and a plurality of calibration terminals integral to the calibration board.

The calibration terminals of the calibration apparatus may have a configuration corresponding to a configuration of outer terminals of the test component. The test component may be a semiconductor package.

### BRIEF DESCRIPTION OF THE DRAWINGS

The above and other features and advantages of the present invention will become more apparent to those of ordinary skill in the art by describing in detail example embodiments thereof with reference to the attached drawings, in which:

FIG. 1 illustrates a plan view of a calibration jig in accordance with an embodiment of the present invention;

FIG. 2 illustrates a plan view of a calibration block in FIG. 1;

FIG. 3 illustrates a cross-sectional view along line III-III′ in FIG. 2;

FIG. 4 illustrates a cross-sectional view along line IV-IV′ in FIG. 2;

FIG. 5 illustrates a plan view of a calibration board in FIG. 1; and

FIG. 6 illustrates a cross-sectional view of a calibration apparatus in accordance with an embodiment of the present invention.

### DETAILED DESCRIPTION OF THE INVENTION

Korean Patent Application No. 2005-97028, filed on Oct. 14, 2005, in the Korean Intellectual Property Office, and entitled: “Calibration Jig And Calibration Apparatus Having the Same,” is incorporated by reference herein in its entirety.

The present invention will now be described more fully hereinafter with reference to the accompanying drawings, in which example embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers, elements, and regions may be exaggerated for clarity of illustration.

It will also be understood that when an element is referred to as being “on” another element or substrate, it can be directly on the other element or substrate, or intervening elements may also be present. Further, it will be understood that when an element is referred to as being “under” another element, it can be directly under, or one or more intervening elements may also be present. In addition, it will also be understood that when an element is referred to as being “between” two elements, it can be the only element between the two elements, or one or more intervening elements may also be present. Likewise, it will be understood that when an element or layer is referred to as being “connected to” or “coupled to” another element or layer, it can be directly connected to or coupled to the other element or layer or intervening elements or layers may be present. In contrast, when an element is referred to as being “directly on,” “directly connected to,” or “directly coupled to” another element or layer, there may be no intervening elements or layers present. Like reference numerals refer to like elements throughout.

As used herein, the term “and/or” may include any and all combinations of one or more of the associated listed items.

As further used herein, the singular forms “a,” “an” and “the” are intended to include the plural forms as well, unless the context clearly indicates otherwise.

Unless otherwise defined, all terminology used herein is given its ordinary meaning in the art, and therefore, should be interpreted within the context of the specification and the relevant art as understood by one of ordinary skill.

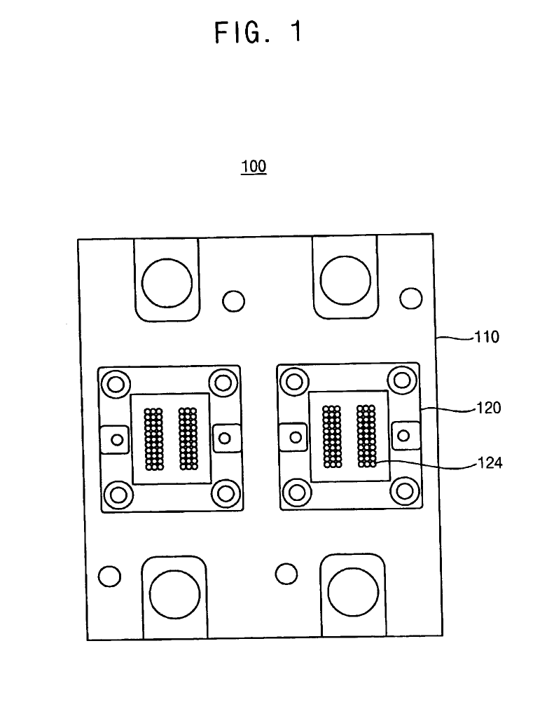

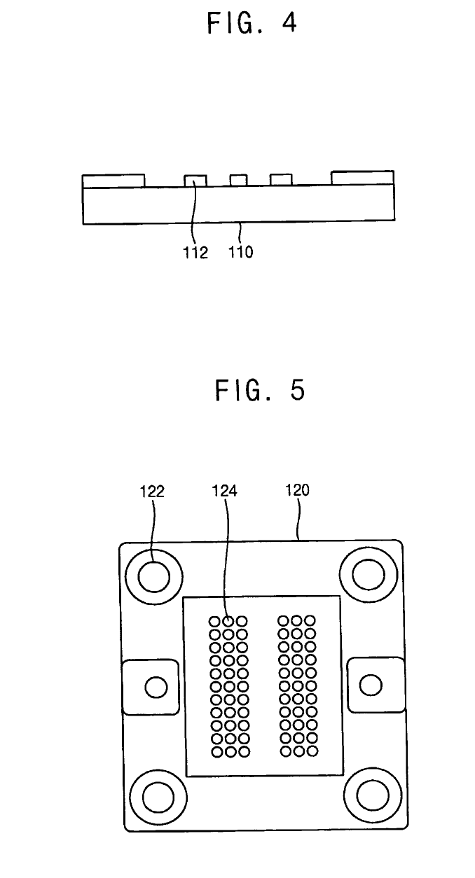

An embodiment of a calibration jig, i.e., calibration jig 100, according to the present invention will now be described in detail with reference to FIGS. 1 to 5. As illustrated in FIG. 1, the calibration jig 100 may include a calibration block 110, a plurality of calibration boards 120, e.g., two calibration boards 120, and a plurality of calibration terminals 124.

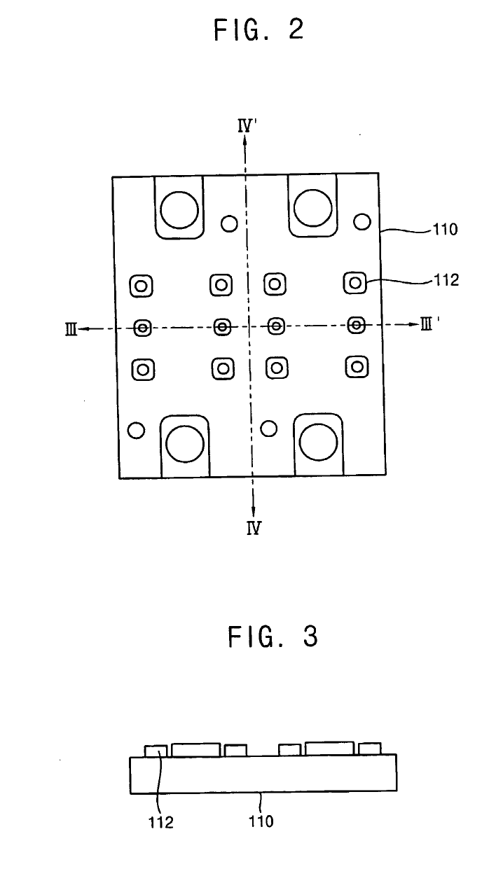

The calibration block 110 according to an embodiment of the present invention may be formed of any suitable material known to a person skilled in the art into a thin rectangular plate, as illustrated in FIG. 2-4. A size of the calibration block 110 may be adjusted with respect to the number of calibration boards 120 secured thereon, as will be discussed below. The calibration block 110 may be positioned on a tester head (not shown) for testing electrical components, i.e., DUT, for example, a semiconductor package.

According to an embodiment of the present invention, the calibration jig 100 may also include any number of calibration boards 120, e.g., one calibration board 120, three calibration boards 120, and so froth, secured to the calibration block 110. In particular, the number of calibration boards 120 may be determined according to manufacturing needs and/or testing convenience. The calibration boards 120 may be shaped as thin rectangular plates. A size of the calibration board 120 may be smaller than the size of the calibration block 110, i.e., dimensions of the rectangular shape of the calibration board 120 may be smaller than dimensions of the rectangular shape of the calibration block 110.

The calibration boards 120 may be assembled simultaneously with the calibration block 110 to form a single structure, i.e., a securing platform, such that each calibration board 120 may secure one test component, e.g., a semiconductor package. The calibration boards 120 secured to the calibration block 110 may also be detachable. In other words, each calibration board 120 may be disassembled from the calibration block 110 and replaced with a different calibration board 120, as will be discussed in detail below.

As further illustrated in FIGS. 2 to 4, the calibration block 110 may include a plurality of primary connecting holes 112 for connecting the plurality of calibration boards 120 to the calibration block 110. In the example embodiment illustrated in FIGS. 2 to 4, six primary connecting holes 112 may be used to secure one calibration board 120 to the calibration block 110. However, any number of the primary connecting holes 112 may be employed in the present invention as may be determined by a person skilled in the art and in accordance with the size and shape of the calibration board 120.

The calibration board 120, as illustrated in FIG. 5, may include a plurality of secondary connecting holes 122 formed in a peripheral portion of the calibration board 120. The number of the secondary connecting holes 122 may equal the number of the primary connecting holes 112. Further, positions of the secondary connecting holes 122 may correspond to positions of the primary connecting holes 112 to facilitate alignment and connection of the calibration boards 120 to the calibration block 110.

The connection of the calibration boards 120 to the calibration block 110 may be done with non-permanent securing members (not shown), e.g., screws, pins, or the like. Such securing members may be inserted through the primary connecting holes 112 and the secondary connecting holes 122 to secure the calibration board 120 to the calibration block 110. Accordingly, a stable, yet impermanent, structure may be assembled, such that replacement of calibration boards 120 may be possible.

The calibration terminals 124 according to an embodiment of the present invention may be integral to the calibration boards 120. In other words, a plurality of calibration terminals 124 may be integrated into a central portion of each calibration board 120, as illustrated in FIG. 5. The number and configuration arrangement of the calibration terminals 124 in each calibration board 120 may correspond to the number and configuration arrangement of the DUT outer terminals, i.e., terminals for signal transmission. In this respect, it should be noted that terminology such as “corresponding to” with respect to terminals' configuration refers to a first plurality of outer terminals that are having the same number and are arranged in the same geometric or planar configuration as a second plurality of outer terminals, such that each terminal of the first plurality of outer terminals may be aligned with a terminal of the second plurality of outer terminals.

For example, when a semiconductor package having a specific configuration of solder balls in its outer terminals is tested, a first calibration board 120 having a corresponding configuration of calibration terminals 124 may be used. When a second DUT having a different configuration of outer terminals is tested, the first calibration board 120 may be disassembled from the calibration block 110, and a second calibration board 120, i.e., a calibration board 120 having calibration terminals 124 that correspond to the outer terminals of the second DUT, may be attached to the calibration block 110 to replace the first calibration board 120 in order to perform a calibration process. In this respect, it should be noted that descriptive terms such as “first” and “second” may refer to elements of an embodiment of the present invention for the purpose of distinguishing one element from another only.

The calibration terminals 124 may electrically connect a calibration source, such as a tester head (not shown), a driver (not shown), or a comparator (not shown) to the DUT by way of the outer terminals of the DUT in order to provide calibration signals, i.e. input/output signals used for calibration. Accordingly, the calibration terminals 124 may provide a transmitting medium for DUT input/output signals for the purpose of calibrating the testing device of the DUT.

The calibration terminals 124 may be formed according to any methods known in the art in order to facilitate signal transfer. For example, the calibration terminals 124 may include conductive balls. Alternatively, the calibration terminals 124 may be formed to have socket shapes. However, other methods of forming calibration terminals known in the art are not excluded from the scope of this invention.

Without intending to be bound by theory, it is believed in accordance with an embodiment of the present invention, that integrating the calibration block 110 and the calibration boards 120 into a single structure, and employing calibration terminals 124 having a corresponding number and configuration to that of a DUT's outer terminals may provide a calibration jig with improved calibration accuracy and a relatively shorter calibration process.

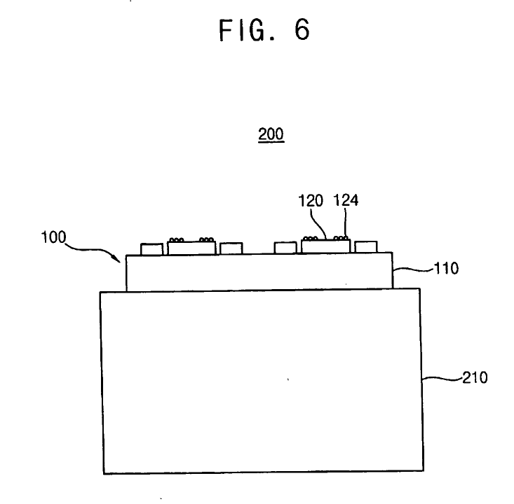

According to another aspect of the present invention, an example embodiment of a calibration apparatus having a calibration jig is discussed below. As illustrated in FIG. 6, a calibration apparatus 200 according to an embodiment of the present invention may include a tester head 210 and a calibration jig 100 secured to the tester head 210. It should be noted that the calibration jig 100 in the calibration apparatus 200, as illustrated in FIG. 6, corresponds to the calibration jig 100 previously discussed with respect to FIGS. 1 to 5. Accordingly, any detailed discussion of the calibration jig 100 configuration, structure, and elements will not be repeated herein.

The tester head 210 may include a driver/comparator (not shown). The driver may generate testing signals, i.e., input signals, and transmit them through the calibration terminals 124 to the DUT, while the DUT may generate response signals, i.e., output signals, and transmit them through the calibration terminals 124 of the calibration board 120 into the comparator.

The input signals and the output signals transmitted through the calibration terminals 124 are compared and analyzed in the driver/comparator in order to adjust timing of the tester head 210, i.e., an operation time of the driver/comparator during testing of the DUT.

Since the calibration terminals 124 may have a configuration that corresponds to a configuration of the outer terminals of a DUT, the calibration accuracy obtained using the calibration apparatus 200 may be substantially increased.

It should be noted that the example embodiments of the calibration jig and calibration apparatus according to the present invention were described with respect to calibration of a tester head in semiconductor packaging testing. However, other embodiments of a calibration jig and a calibration apparatus that may be employed for calibrating tester heads for other electronic parts are not excluded from the scope of this invention.

Example embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A calibration jig for adjusting timing, comprising:
a calibration block;
at least one calibration board attached to the calibration block to form a securing platform for at least one test component; and
a plurality of calibration terminals integral to the calibration board.

2. The calibration jig as claimed in claim 1, wherein the calibration terminals have a configuration corresponding to a configuration of outer terminals of the test component.

3. The calibration jig as claimed in claim 1, wherein the calibration terminals comprise a conductive ball.

4. The calibration jig as claimed in claim 1, wherein the calibration terminals are electrically connecting the test component to a calibration source.

5. The calibration jig as claimed in claim 1, wherein the calibration board is detachable.

6. The calibration jig as claimed in claim 1, further comprising a plurality of calibration boards.

7. The calibration jig as claimed in claim 1, wherein the test component is a semiconductor package.

8. A calibration apparatus, comprising:
a tester head;
a calibration block attached to the tester head;
at least one calibration board attached to the calibration block to form a securing platform for at least one test component; and
a plurality of calibration terminals integral to the calibration board.

9. The calibration apparatus as claimed in claim 8, wherein the calibration terminals have a configuration corresponding to a configuration of outer terminals of the test component.

10. The calibration apparatus as claimed in claim 8, wherein the test component is a semiconductor package.
